(19) United States
(12) Patent Application Publication
(10) Pub. No.: US 2008/0173887 A1
(43) Pub. Date: Jul. 24, 2008

(54) Self-luminous device

(75) Inventors: Toshihiko Baba, Yokohama-shi (JP); Kosuke Morito, Yokohama-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Stanley Electric Co., Ltd., Tokyo (JP)

(21) Appl. No.: 11/906,074

(22) Filed: Sep. 28, 2007

Related U.S. Application Data
(63) Continuation of application No. PCT/JP2006/305167, filed on Mar. 15, 2006.

(30) Foreign Application Priority Data
Mar. 28, 2005 (JP) 2005-092412
Jul. 13, 2005 (JP) 2005-204976

(51) Int. Cl. H01L 33/00

(52) U.S. Cl. 257/98; 257/E33.012

(57) ABSTRACT

A self-luminous device 1 is one embodiment which has an increased light extraction efficiency by optimizing the distribution of refractive index in semiconductor layers. The self-luminous device 1 includes a first layer (semiconductor layer 2), a light emitting layer 3 overlaying the first layer (semiconductor layer 2), and a second layer (semiconductor layer 4) overlaying the light emitting layer 3. The first layer (semiconductor layer 2) and the second layer (semiconductor layer 4) have different refractive indices so that the refractive indices of the two layers (semiconductor layers 2 and 4) are asymmetric with respect to the light emitting layer interposed therebetween. In the refractive index distribution of asymmetric layers (semiconductor layers), the refractive index of the second layer (semiconductor layer 4) is higher than that of the first layer (semiconductor layer 2).

### CROSS-REFERENCE TO RELATED APPLICATIONS

This application is a Continuation Application of International Application PCT/JP2006/305167, filed Mar. 15, 2006, which is incorporated by reference herein.

This application claims the benefit of priority under 35 USC 119 of Japanese Patent Applications No. 2005-092412 filed on Mar. 28, 2005, and No. 2005-204976 filed on Jul. 13, 2005, which are incorporated by reference herein.

### BACKGROUND OF THE INVENTION

1. Field of the Invention

The present invention relates to self-luminous devices, such as light emitting diodes (LEDs) and organic electroluminescent (EL) devices.

2. Description of the Related Art

Self-luminous devices, such as light emitting diodes (LEDs) and organic electroluminescent (EL) devices, are expected to be used in a wide range of applications, including signs, displays and illuminations. One drawback of these devices is that the efficiency of light utilization is low since the light emitted from the illuminants is not effectively extracted outside due to the total internal reflection. For example, the efficiency of luminous devices using an LED or other semiconductors is said to be 10% or less.

Thus, a way is needed to effectively extract the light emitted from the illuminants of the self-luminous devices into the air.

One approach is to form a periodic structure in the surface of a semiconductor (See, for example, U.S. Pat. No. 5,779,924, Japanese Patent Application Laid-Open No. Hei 10-4209, Japanese Patent Application Laid-Open No. 2004-128445 and Japanese Patent Application Laid-Open No. 2004-31221). The periodic structure in the surface of a semiconductor serves to change the wavenumber of the internal light and thus, its direction, so that the internal light can no longer undergo the total internal reflection and can thus be extracted into the air. In this technique, the large solid angle of the internal light improves the extraction efficiency of the light.

Using a three-dimensional light wave simulation technique, the present inventors confirmed that the extraction efficiency of self-luminous devices featuring the above-described periodic structure was limited by the diffraction efficiency of the periodic structure and was at most 1.5 times to twice that of the conventional self-luminous devices. With regard to the three-dimensional light wave simulation, the present inventors have previously filed a patent application entitled “Method for Wave Optics Simulation” (Japanese Patent Application Laid-Open No. 2005-69709).

One problem of the periodic structure approach is that the structure may not be made with perfect periodicity depending on the type of the process used to make it. Such defective periodic structures cannot achieve sufficiently high light extraction efficiency. Also, making the periodic structure with perfect periodicity requires an elaborate process.

One approach to significantly improve the light extraction efficiency is to integrate a diffraction grating into the light emitting layer (active layer). However, the quality of the light emitting layer is significantly affected by the integration of the diffraction grating, making this approach impractical.

### SUMMARY OF THE INVENTION

In view of the foregoing, it is an object of the present invention to effectively extract the light emitted from the illuminants used in self-luminous devices into the air.

It is another object to improve the light extraction efficiency of self-luminous devices without requiring elaborate processes.

It is still another object of the present invention to improve the light extraction efficiency of self-luminous devices having a periodic structure with imperfect periodicity.

By using the above-described three-dimensional light wave simulation technique, the present inventors have analyzed the light emitted from self-luminous devices and have found that one of the key factors that affects the light extraction efficiency is the distribution of refractive index in the semiconductor layer or other layers that form the self-luminous device.

When the light emitting surface of self-luminous devices includes a two-dimensional periodic structure, the light extraction efficiency may also be affected by the geometry of the two-dimensional periodic structure and the distance between the light emitting layer and the two-dimensional periodic structure.

The self-luminous device of the present invention has been devised based on the knowledge obtained by the simulation and comprises four embodiments for improving the light extraction efficiency.

A first embodiment of the self-luminous device of the present invention improves the light extraction efficiency by optimizing the distribution of refractive index of each layer constituting the self-luminous device. Specifically, a self-luminous device may be constructed that includes a first layer, a light emitting layer overlaying the first layer, and a second layer overlaying the light emitting layer. The first layer and the second layer have different refractive indices so that the refractive indices of the two layers are asymmetric with respect to the light emitting layer interposed therebetween.

The second layer has a higher refractive index than the first layer to establish the asymmetric refractive index distribution.

In the first embodiment, the asymmetric refractive index distribution with respect to the light emitting layer facilitates the extraction of light confined in the light emitting layer since the light distribution in a self-luminous device consisting of layers with asymmetric refractive index distribution differs from that in a self-luminous device consisting of layers with symmetric refractive index distribution.

By increasing the refractive index of the second layer higher than that of the first layer, light extracted from the light emitting layer is guided to the second layer that has a higher refractive index than the first layer. This improves the light extraction efficiency from the light emitting surface of the second layer.

The first embodiment with the configuration of the asymmetric refractive index distribution with respect to the light emitting layer may be applied to a self-luminous device with or without the two-dimensional periodic structure formed on the light emitting surface thereof.

A second embodiment of the self-luminous device of the present invention concerns a self-luminous device that has a two-dimensional periodic structure formed on the light emitting surface thereof. This embodiment improves the light extraction efficiency by optimizing the distance between the light emitting layer and the two-dimensional periodic structure. Specifically, the self-luminous device includes a first layer, a light emitting layer overlaying the first layer, and a second layer overlaying the light emitting layer. A two-dimensional periodic structure is formed either in the surface of the second layer or in the surface of a layer overlaying the second layer. The self-luminous device is constructed such that, given that λ is the wavelength of light in vacuum, the distance between the top of the light emitting layer and the bottom of the two-dimensional periodic structure is 0.1λ to 0.3λ, or 0.3λ to λ. The distance is substantially the same as, or greater than, the penetration depth in the evanescent region.

When the distance between the top of the light emitting layer and the bottom of the two-dimensional periodic structure is relatively large (0.3λ to λ), the extraction of freely emitted internal light is increased, resulting in an increase in the light extraction efficiency. When the distance between the top of the light emitting layer and the bottom of the two-dimensional periodic structure is relatively small (0.1λ to 0.3λ), the light extraction is increased, as is the radiation to the outside. This also leads to an increase in the light extraction efficiency.

The second embodiment may be combined with the first embodiment: A self-luminous device may be constructed in which the distance between the bottom of the two-dimensional periodic structure on the light emitting surface and the top of the light emitting layer is 0.1λ to 0.3λ, or 0.3λ to λ, and in which the first layer and the second layer have different refractive indices so that the refractive indices of the two layers are asymmetric with respect to the light emitting layer interposed therebetween. The refractive index of the second layer is preferably higher than that of the first layer.

As in the first embodiment, a third embodiment of the self-luminous device of the present invention improves the light extraction efficiency by optimizing the refractive index distribution of the layers of the self-luminous device. Specifically, the self-luminous device has a multilayer construction including a first layer, a light emitting layer overlaying the first layer, a second layer overlaying the light emitting layer, and an intermediate layer formed within the second layer.

The intermediate layer has substantially the same refractive index as the light emitting layer and is made of a medium that does not absorb the light emitted from the light emitting layer. Alternatively, the intermediate layer may have a higher refractive index than the first layer and the second layer. The intermediate layer is 0.5λ or greater in thickness (where λ is the wavelength of light in vacuum).

The third embodiment may be combined with the second embodiment: A self-luminous device may be constructed in which the two-dimensional periodic structure is formed on the second layer and the intermediate layer is formed within the two-dimensional periodic structure so as to make a multilayer structure, with the distance between the bottom of the two-dimensional periodic structure and the top of the light emitting layer being 0.1λ to 0.3λ, or 0.3λ to λ.

The first layer, the second layer and the intermediate layer are formed of AlGaN with the Al composition in the intermediate layer being smaller than in the first layer and the second layer. This makes the refractive index of the intermediate layer higher than those of the first layer and the second layer.

In the second and third embodiments, the two-dimensional periodic structure may be a dense array of circular pores or a dense array of cone-shaped projections. The cone-shaped projections may be conical, pyramidal or any other desired shape.

The two-dimensional periodic structure may be formed of photonic crystals or photonic quasicrystals.

The photonic quasicrystals form on the light emitting surface of the illuminant a quasiperiodic structure that does not have translational symmetry, but does have long-range order and rotational symmetry in terms of refractive index. This structure can be formed by arranging on the light emitting surface of the illuminant refractive index regions forming photonic crystals in a quasicrystal pattern that does not have translational symmetry.

When the first layer and the second layer in the first, second or third embodiment are semiconductor layers, the first semiconductor layer, the light emitting layer and the second semiconductor layer can be formed of n-GaN (or p-GaN), InGaN and p-GaN (or n-GaN), respectively.

In the first, second or third embodiment, the second layer may be coated with a resin layer.

By using the quasiperiodic structure of photonic quasicrystals as the two-dimensional periodic structure, the dependency on the bandwidth can be decreased, as can the dependency on the angle of view, and the efficiency can be improved for large solid angles as well as for wide spectra. As a result, the light emitted from the illuminants can be effectively extracted into the air.

Aside from semiconductors, the first layer and the second layer may also be formed of glass substrate to make light emitting diodes and organic EL devices.

A fourth embodiment of the present invention improves the light extraction efficiency by including a two-dimensional periodic structure on the light emitting surface and, as in the first embodiment, by optimizing the refractive index distribution for the layers of the self-luminous device.

Specifically, the fourth embodiment includes a first layer, a light emitting layer overlaying the first layer, and a second layer overlaying the light emitting layer. A two-dimensional periodic structure is formed either in the surface of the second layer or in the surface of a layer overlaying the second layer. The first layer is a low refractive index layer that has a refractive index lower than that of the light emitting layer and equal to or lower than that of the second layer. The low refractive index layer has a thickness substantially equal to the wavelength of the light emitted from the light emitting layer.

In the fourth embodiment, the light emitting layer is formed of InGaN and the first layer having a low refractive index is formed of any of AlGaN, Al₂O₃ (sapphire) or AlN (aluminum nitride).

One exemplary construction of the fourth embodiment of the self-luminous device consists of a sapphire substrate overlaid with an InGaN light emitting layer and an AlGaN layer having a two-dimensional periodic structure. The self-luminous device has an electrode layer disposed between the sapphire substrate and the light emitting layer and the other electrode forming a part of the AlGaN layer, thereby providing an electric current to the light emitting layer.

In the self-luminous device having a two-dimensional periodic structure in accordance with the present invention, the periodicity of the two-dimensional periodic structure has a period of ½ to 2 periods. Sufficient efficiency is achieved by the self-luminous device as long as the deviation of period remains within this range.

As set forth, the present invention makes it possible to extract the light emitted from illuminants used in self-luminous devices into the air. In addition to this, the light extraction efficiency of self-luminous devices is significantly improved without requiring elaborate processes.

The present invention ensures high light extraction efficiency even when the periodicity of the periodic structure is insufficient.

### BRIEF DESCRIPTION OF THE DRAWINGS

FIG. 1 is a diagram illustrating a first embodiment of the present invention.

FIGS. 2A through 2D are diagrams illustrating a second embodiment of the present invention.

FIGS. 3A through 3E are diagrams showing the relationship between the periodicity of the two-dimensional periodic structure and the output.

FIGS. 4A through 4C are diagrams illustrating a third embodiment of the present invention.

FIGS. 5A through 5C are diagrams illustrating a fourth embodiment of the present invention.

FIGS. 6A through 6F are diagrams illustrating the results of a simulation conducted to determine the efficiency at which light is extracted from self-luminous devices with different flat surface structures that do not include the two-dimensional periodic structure of the present invention.

FIGS. 7A through 7K are diagrams illustrating the results of a simulation conducted to determine the efficiency at which light is extracted from different self-luminous devices each having a dense array of circular pores as the two-dimensional periodic structure of the present invention.

FIGS. 8A through 8K are diagrams illustrating the results of a simulation conducted to determine the efficiency at which light is extracted from different self-luminous devices each having a dense array of conical projections as the two-dimensional periodic structure of the present invention.

FIGS. 9A through 9F are diagrams illustrating the results of a simulation conducted to determine the efficiency at which light is extracted from self-luminous devices having different flat surface structures each covered with a resin coating of the present invention.

FIGS. 10A through 10J are diagrams illustrating the results of a simulation conducted to determine the efficiency at which light is extracted from different self-luminous devices each having a dense array of circular pores as the two-dimensional periodic structure and covered with a resin coating in accordance with the present invention.

FIGS. 11A through 11J are diagrams illustrating the results of a simulation conducted to determine the efficiency at which light is extracted from different self-luminous devices each having a dense array of conical projections as the two-dimensional periodic structure and covered with a resin coating in accordance with the present invention.

FIG. 12 is a diagram showing the results of a simulation conducted on a series of self-luminous devices of the present invention.

FIG. 13 is a diagram showing the results of a simulation conducted on a series of self-luminous devices of the present invention.

FIGS. 14A through 14C are diagrams illustrating one exemplary construction of the fourth embodiment of the self-luminous device of the present invention.

FIGS. 15A through 15D are diagrams illustrating a process for making the construction of the fourth embodiment of the self-luminous device of the present invention.

### DETAILED DESCRIPTION

Several embodiments of the present invention will now be described in detail with reference to the accompanying drawings. Although the self-luminous device of the present invention is described with reference to exemplary constructions each consisting of semiconductor layers (as is the case with light emitting diodes), it may also be applied to organic EL devices and other devices that consist of layers of glass substrate.

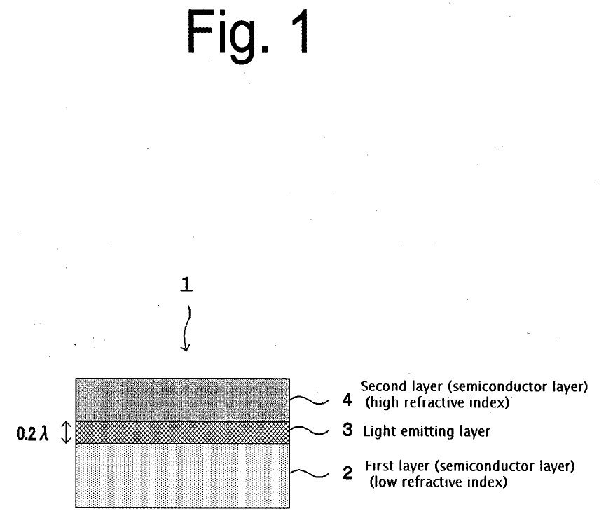

A first embodiment of the present invention will now be described with reference to FIG. 1. Referring to FIG. 1, a self-luminous device 1 of the first embodiment improves the light extraction efficiency by optimizing the distribution of refractive indices of semiconductor layers. The self-luminous device 1 includes a first semiconductor layer 2, a light emitting layer 3 overlaying the first semiconductor layer 2, and a second semiconductor layer 4 overlaying the light emitting layer 3. The first semiconductor layer 2 has a relatively low refractive index and the second semiconductor layer 4 has a relatively high refractive index so that the distribution of refractive indices of the semiconductor layers 2, 4 is asymmetric with respect to the light emitting layer 3 interposed therebetween.

The semiconductor layers 2, 4 and the light emitting layer 3 together form the self-luminous device 1. In one construction, each of the first semiconductor layer 2 and the second semiconductor layer 4 may be formed as a cladding layer made of AlGaN and the light emitting layer 3 may be made of InGaN. In such a case, the light emitting layer 3, the first semiconductor layer 2 (cladding layer of AlGaN) and the second semiconductor layer 4 (cladding layer of AlGaN) have refractive indices of, for example, 2.8, 2.5 and 2.78, respectively. The refractive index of the second semiconductor layer 4 (cladding layer of AlGaN) can be made higher than that of the first semiconductor layer 2 (cladding layer of AlGaN) by decreasing the Al composition of the second semiconductor layer 4 as compared to the Al composition of the first semiconductor layer 2. The light emitting layer 3 preferably has a thickness of 0.2λ (where λ is the wavelength of light in vacuum).

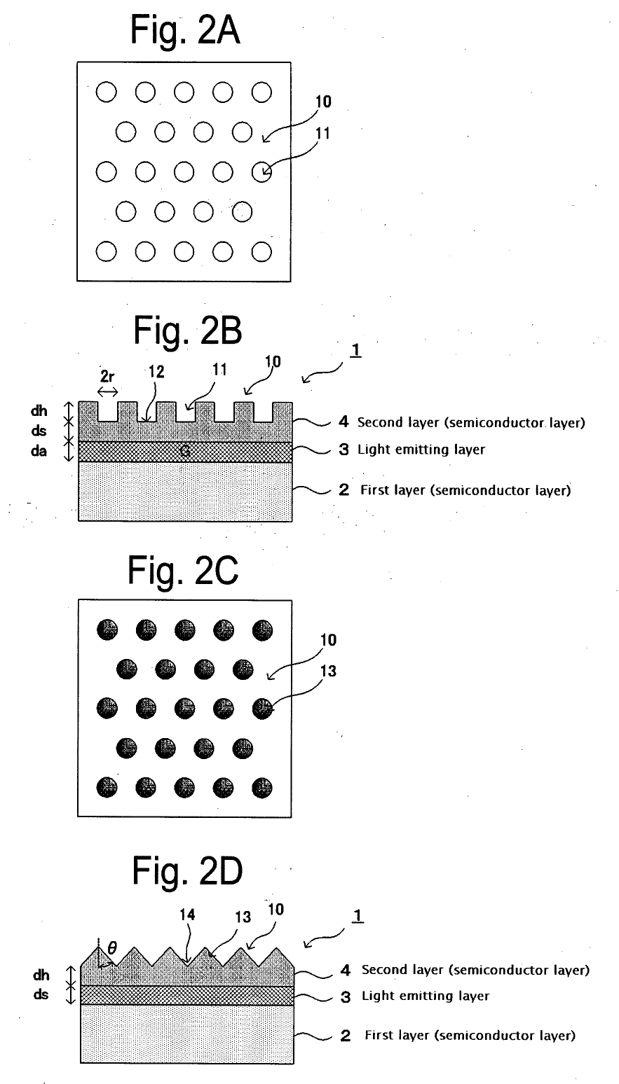

A second embodiment of the present invention will now be described with reference to FIG. 2. Referring to FIG. 2, a self-luminous device 1 of the second embodiment includes a two-dimensional periodic structure 10 formed on its light emitting surface. This embodiment improves the light extraction efficiency by optimizing the distance (ds) between the light emitting layer 3 and the two-dimensional periodic structure 10. The two-dimensional periodic structure may be formed in the surface of the semiconductor layer itself or in the surface of a layer that overlays the semiconductor layer. In the following example, the two-dimensional periodic structure is formed on the semiconductor layer.

The self-luminous device 1 includes a first semiconductor layer 2, a light emitting layer 3 overlaying the first semiconductor layer 2, and a second semiconductor layer 4 overlaying the light emitting layer 3. A two-dimensional periodic structure 10 is formed in the surface of the second semiconductor layer 4. The distance between the top of the light emitting layer 3 and the bottom of the two-dimensional periodic structure 10 is 0.1 to 0.3λ, or 0.3λ to λ (where λ is the wavelength of light in vacuum). The distance (ds) is substantially the same as, or greater than, the penetration depth in the evanescent region.

As in the first embodiment, the semiconductor layers 2, 4 and the light emitting layer 3 together form the self-luminous device 1. In one construction, each of the first semiconductor layer 2 and the second semiconductor layer 4 may be formed as a cladding layer made of AlGaN and the light emitting layer 3 may be made of InGaN.

The distribution of refractive indices of the first semiconductor layer 2, the light emitting layer 3 and the second semiconductor layer 4 may be either asymmetric as in the first embodiment, or symmetric. In the asymmetric construction, the light emitting layer 3, the first semiconductor layer 2 (cladding layer of AlGaN) and the second semiconductor layer 4 (cladding layer of AlGaN) may have refractive indices of, for example, 2.8, 2.5 and 2.78, respectively. In the symmetric construction, the light emitting layer 3 may have a refractive index of, for example, 2.8 while the first semiconductor layer 2 (cladding layer of AlGaN) and the second semiconductor layer 4 (cladding layer of AlGaN) each have refractive index of, for example, 2.5.

In the second embodiment, the two-dimensional periodic structure 10 may be a dense array of circular pores or a dense array of cone-shaped projections and may be formed of photonic crystals or photonic quasicrystals. Cone-shaped projections such as conical projections, pyramidal projections or projections of any desired shape may be densely arrayed to form the dense array of cone-shaped projections.

The photonic crystals are formed by arranging regions of different refractive indices in a repetitive pattern with a period substantially equal to the wavelength of light. The photonic quasicrystals are formed by arranging, in accordance with a repetitive quasicrystal pattern, patterns of photonic crystals that have two types of regions having two different refractive indices in which the two regions alternately repeat with a period substantially equal to the wavelength of light. The photonic quasicrystals have a quasiperiodic structure of refractive index that does not have translational symmetry, but does have long-range order and rotational symmetry in terms of refractive index. The quasicrystals may form different patterns including a Penrose tiling (Penrose-type) pattern and a square-triangle tiling (12-fold symmetric) pattern.

The light emitting surface having a grating structure of photonic quasicrystals serves to increase the light extraction efficiency and decrease the dependency on the angle of view, allowing a large solid angle.

FIGS. 2(a) and (b) show the two-dimensional periodic structure formed as a dense array of circular pores. FIG. 2(a) is a plan view of the two-dimensional periodic structure 10 (i.e., dense array of circular pores) and FIG. 2(b) is a side view of the self-luminous device 1 and the two-dimensional periodic structure 10.

The self-luminous device 1 having this type of two-dimensional periodic structure (dense array of circular pores) includes an array of circular pores 11 regularly arranged on the second semiconductor layer 4. The diameter of each pore is given as 2r and the depth as dh. The distance between the bottom 12 of the circular pore 11 and the top of the light emitting layer 3 is indicated as ds. The two-dimensional periodic structure has a grating constant a (i.e., pitch between pores), a parameter that defines the structure.

The results of a three-dimensional light wave simulation have demonstrated that the light extraction efficiency varies as a function of parameters a, 2r and dh and maximizes when a=λ to 1.5λ, 2r=0.5a to 0.6a, and dh=0.5λ to λ.

FIG. 2(c) is a plan view of the two-dimensional periodic structure 10 formed as a dense array of conical projections with FIG. 2(d) showing a side view of the self-luminous device 1 and the two-dimensional periodic structure 10.

Although the projections described in this example are each formed as a cone, the projections having other shapes, such as pyramidal projections, may be arranged in a dense array.

The self-luminous device 1 having this type of two-dimensional periodic structure (dense array of conical projections) includes an array of conical projections 13 regularly arranged on the second semiconductor layer 4 (The light emitting surface is entirely covered with the conical projections). Each conical projection 13 has an angle θ. The distance between the bottom 14 of the conical projection 13 and the top of the light emitting layer 3 is indicated as ds. The two-dimensional periodic structure has a grating constant a (i.e., pitch between conical projections) and the angle θ, each a parameter that defines the structure.

The results of a three-dimensional light wave simulation have demonstrated that the light extraction efficiency varies as a function of parameters a and θ and maximizes when a=0.5λ to λ, and θ=60° to 65°.

As will be described later, the light extraction efficiency of the self-luminous device 1 is determined relative to the standard (i.e., the light extraction efficiency of a flat surface self-luminous device that does not include any two-dimensional periodic structures).

The results of a three-dimensional light wave simulation have proven that the light extraction efficiency improves when the distance ds between the top of the light emitting layer 3 and the bottom of the two-dimensional periodic structure 10 (the bottom 12 of the array of circular pores in FIG. 2(b) or the bottom 14 of the array of conical projections in FIG. 2(d)) is 0.1λ to 0.3λ, or 0.3λ to λ.

When the distance between the top of the light emitting layer and the bottom of the two-dimensional periodic structure is relatively large (ds=0.3λ to λ), the extraction of freely emitted internal light from the light emitting layer 3 is increased, resulting in an increase in the light extraction efficiency. When the distance between the top of the light emitting layer and the bottom of the two-dimensional periodic structure is relatively small (ds=0.1λ to 0.3λ), the light distribution is varied so as to increase the light extraction from the light emitting layer, as well as the radiation from the light emitting surface. This also leads to an increase in the light extraction efficiency.

The two-dimensional periodic structure may be formed by transferring molded or cast projections onto a semiconductor substrate or an organic EL substrate, or it may be formed by using epitaxial or other etching processes.

The formation of the two-dimensional periodic structure involves etching the semiconductor layer. The semiconductor layer must be etched to the proximity of the light emitting layer in the regions that correspond to the bottoms of the two-dimensional periodic structure. How far the semiconductor layer must be etched depends on the distance ds. Thus, the light emitting layer tends to be damaged during the processing when the distance ds between the top of the light emitting layer and the bottom of the two-dimensional periodic structure is small.

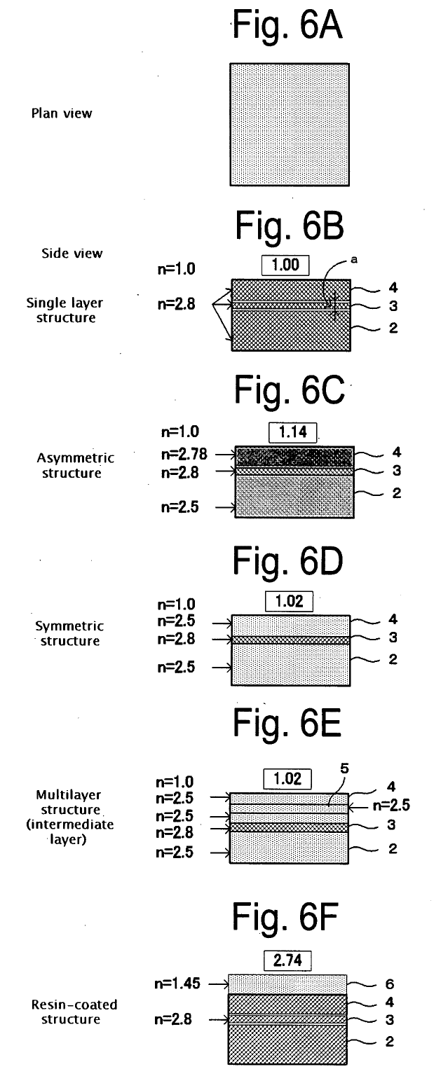

The problem of damaging the light emitting layer during processing can be avoided by combining the first embodiment in which the semiconductor layers have asymmetric refractive indices with a large distance ds (0.3λ to λ). As will be described later with reference to FIG. 6, the light extraction efficiency in such a construction can be maintained at F=3.61, where F is defined as the ratio of light extraction efficiency relative to the standard (i.e., light intensity extracted from a self-luminous device that does not have any two-dimensional periodic structures or any of the features of the first to the fourth embodiments described above).

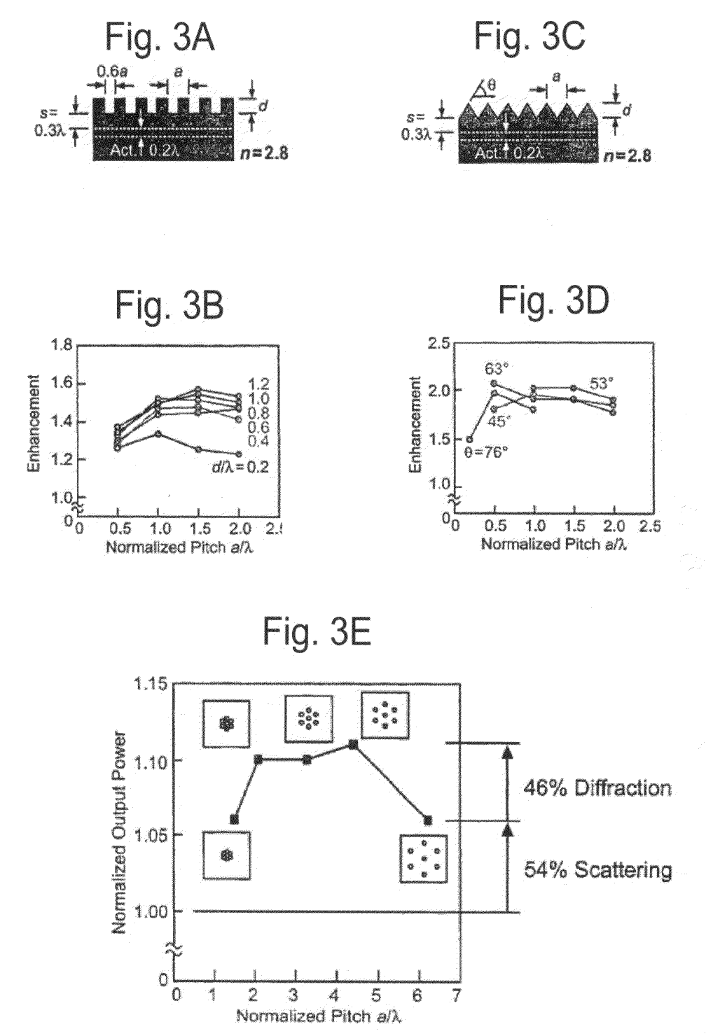

The periodicity of the two-dimensional periodic structure can tolerate a deviation in the range of ½ to 2 periods. FIG. 3 shows the relationship between the periodicity of the two-dimensional periodic structure and the output.

FIGS. 3(a) and 3(b) show an example in which the two-dimensional periodic structure is a dense array of circular pores. FIG. 3(b) shows the intensity (vertical axis) for different values of d/λ (as parameter) with respect to the pitch normalized to a/λ (horizontal axis) in the two-dimensional periodic structure shown in FIG. 3(a). FIGS. 3(c) and 3(d) show an example in which the two-dimensional periodic structure is a dense array of conical projections. FIG. 3(d) shows the intensity (vertical axis) for different values of θ (as parameter) with respect to the pitch normalized to a/λ (horizontal axis) in the two-dimensional periodic structure shown in FIG. 3(c).

FIGS. 3(a) through 3(d) demonstrate that the output is significantly increased when the pitch a/λ is in the range of 0.5 to 2.0. This suggests that the periodicity of the two-dimensional periodic structure can tolerate a deviation in the range of 0.5 to 2.0 as represented by the normalized pitch a/λ.

FIG. 3(e) shows the relationship between the deviation in the periodicity of the two-dimensional periodic structure, the scattering and the diffraction. As can be seen in FIG. 3(e), the output increases as the normalized pitch a/λ (a: grating constant, λ: wavelength) increases from 1 to 6. The figure shows the degree of contribution of the scattering and the diffraction.

As can be seen in FIG. 3(e), the periodicity of the two-dimensional periodic structure can tolerate a deviation in the range of 1.0 to 6.0 as represented by the normalized pitch a/λ.

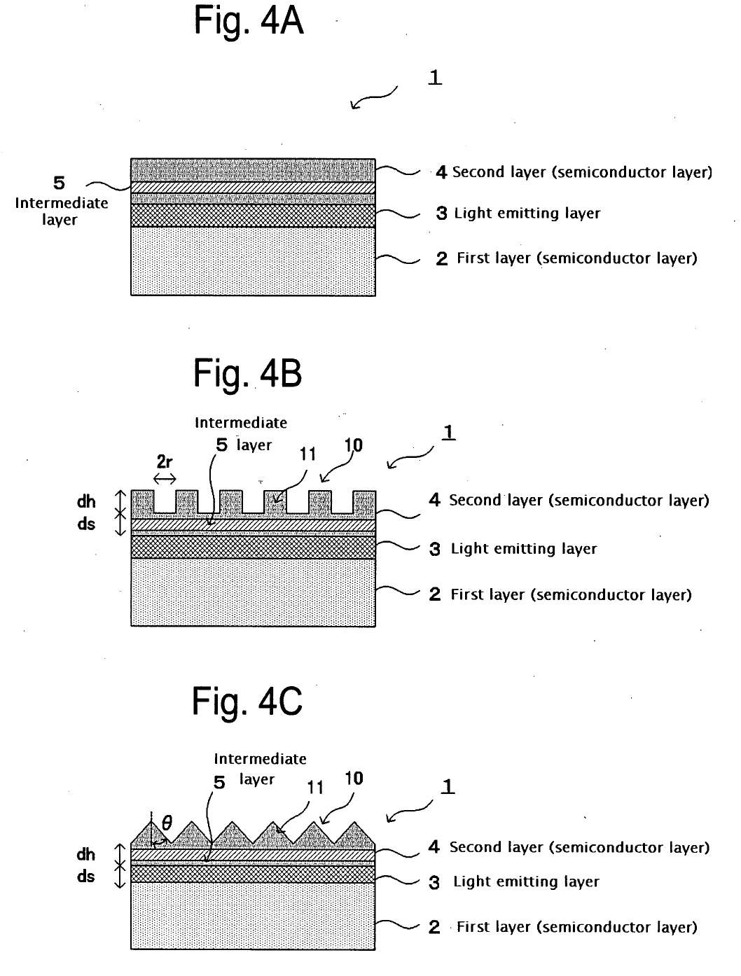

A third embodiment of the present invention is now described with reference to FIG. 4.

Referring to FIG. 4, a self-luminous device 1 of the third embodiment is shown. As in the first embodiment, the self-luminous device of the third embodiment improves the light extraction efficiency by optimizing the distribution of refractive index in the semiconductor layers that form the self-luminous device. This embodiment is characterized by its multilayer structure including an intermediate layer.

The self-luminous device 1 has a multilayer structure comprising a first semiconductor layer 2, a light emitting layer 3 overlaying the first semiconductor layer 2, a second semiconductor layer 4 overlaying the light emitting layer 3, and an intermediate layer 5 within the second semiconductor layer 4.

A first form of the intermediate layer 5 has a refractive index close to that of the light emitting layer 3 and is formed of a medium that does not absorb the light emitted from the light emitting layer 3. A second form of the intermediate layer 5 has a refractive index higher than that of the semiconductor layers 2, 4. The intermediate layer 5 has a thickness of, for example, 0.5λ or greater (where λ is the wavelength of light in vacuum).

For example, when the semiconductor layers 2, 4 are each a cladding layer of AlGaN having a refractive index of 2.5 and the light emitting layer 3 formed of InGaN has a refractive index of 3.0, the refractive index of the intermediate layer 5 may be adjusted to a value of 2.8 by decreasing the Al composition in AlGaN.

The third embodiment may be combined with the second embodiment: The self-luminous device may have a multilayer structure comprising a two-dimensional periodic structure 10 formed on the second semiconductor layer and an intermediate layer 5 disposed within the two-dimensional periodic structure 10, with the distance between the bottom of the two-dimensional periodic structure and the top of the light emitting layer being 0.1λ to 0.3λ, or 0.3λ to λ.

FIG. 4(a) shows an exemplary construction in which the light emitting surface does not include two-dimensional periodic structure. FIG. 4(b) shows another exemplary construction in which the light emitting surface includes a dense array of circular pores as the two-dimensional periodic structure. FIG. 4(c) shows still another exemplary construction in which the light emitting surface includes a dense array of conical projections as the two-dimensional periodic structure.

The multilayer self-luminous device can provide the same effects as the asymmetric, relatively thin construction in which the distance ds is 0.1λ to 0.3λ. This is because the light guided by the light emitting layer is coupled to the second high refractive index semiconductor layer and is strongly diffracted by the grating of the two-dimensional periodic structure.

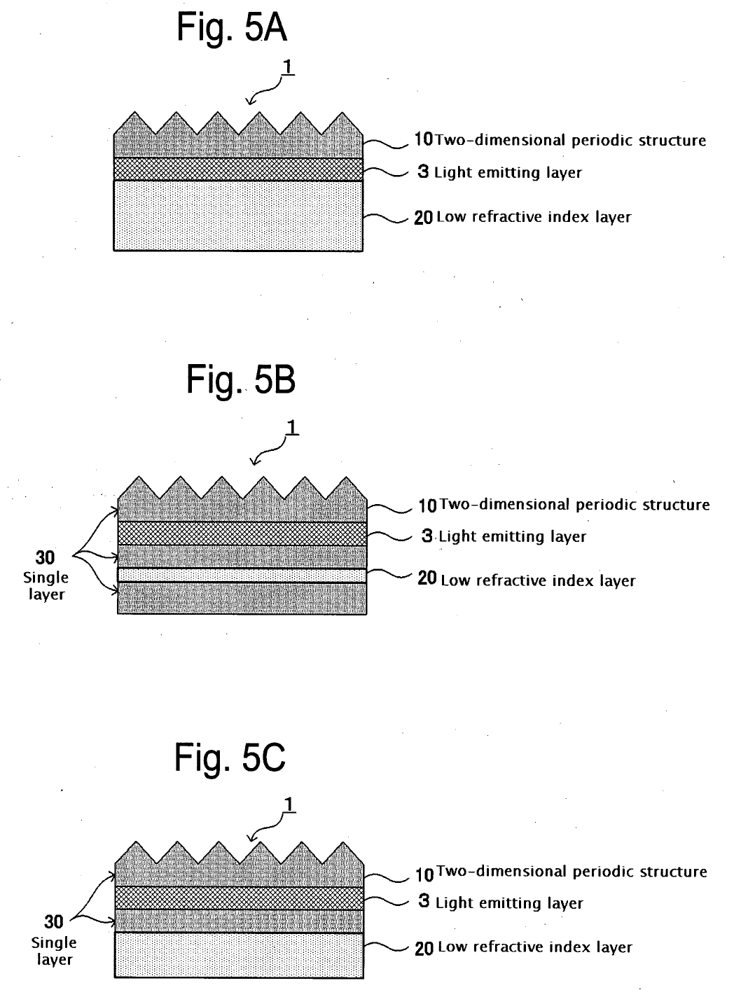

Next, a fourth embodiment of the present invention is described with reference to FIG. 5.

Referring to FIG. 5, a self-luminous device 1 of the fourth embodiment is shown that improves the light extraction efficiency by including a two-dimensional periodic structure 10 in the light emitting surface and, as in the first embodiment, by optimizing the distribution of refractive index in the layers of the self-luminous device.

The self-luminous device 1 of the fourth embodiment includes a first layer, a light emitting layer overlaying the first layer, and a second layer overlaying the light emitting layer. A two-dimensional periodic structure is formed either in the surface of the second layer or in the surface of a layer overlaying the second layer. The first layer is a low refractive index layer that has a refractive index lower than that of the light emitting layer and equal to or lower than that of the second layer.

The fourth embodiment may comprise different forms, as shown in FIG. 5(a) through FIG. 5(c).

Referring to FIG. 5(a), a first form of the fourth embodiment includes a first low refractive index layer 20 disposed directly below the light emitting layer 3.

When sufficient adhesion is not achieved between the light emitting layer 3 and the low refractive index layer 20 that are directly joined, another layer, such as a semiconductor layer (e.g., p-GaN layer), may be disposed between the low refractive index layer 20 and the light emitting layer 3. The interposed semiconductor layer may include one of the electrodes for supplying an electric current to the light emitting layer 3. A p-GaN layer is effectively used as the interposed layer between the low refractive index layer 20 and the light emitting layer 3 since it can decrease the electric resistance and the thickness of the device.

Referring to FIG. 5(b), a second form of the fourth embodiment includes a single layer 30 that forms the two-dimensional periodic structure 10 above the light emitting layer 3 and the semiconductor layer below the light emitting layer 3. A low refractive index layer 20 is disposed within the single layer below the light emitting layer 3.

Referring to FIG. 5(c), a third form of the fourth embodiment also includes a single layer 30 that form the two-dimensional periodic structure 10 above the light emitting layer 3 and the semiconductor layer below the light emitting layer 3. In this construction, a low refractive index layer 20 is disposed below the single layer 30.

In the fourth embodiment, the low refractive index layer 20 has a refractive index lower than that of the light emitting layer 3 and equal to or lower than that of the other layers that form the two-dimensional periodic structure.

Although the low refractive index layer 20 of the fourth embodiment may be constructed as a multilayer film that has gradually changing refractive indices, rather than as a layer having a single refractive index, the fourth embodiment of the present invention is characterized in that it improves the light extraction efficiency by simply providing a low refractive index layer below the light emitting layer.

It is desirable that the low refractive index layer has substantially the same thickness as the wavelength of light emitted from the light emitting layer. For example, when the refractive index in the vicinity of the light emitting layer is 2.4 and the refractive index of the low refractive index layer is 2.2, the light emitting layer emits light with a wavelength of approximately 0.5 μm, which is equal to the wavelength of blue LED. Under such condition, the enhancement of the light emitting efficiency increases as the thickness of the low refractive index layer is increased. The enhancement reaches saturation when the thickness of the low refractive index layer is substantially the same as the wavelength (approximately 0.5 μm). The thickness of the low refractive index layer may vary to some degree as long as the thickness is substantially the same as the wavelength: The low refractive index layer that is 0.4 μm thick can significantly enhance the light emitting efficiency.

What is meant by saying that “the enhancement reaches saturation when the thickness of the low refractive index layer is substantially the same as the wavelength” is that the low refractive index layer provides the same effects when the thickness exceeds the wavelength.

The thickness of the low refractive index layer, which has substantially the same thickness as the wavelength, is typically more than several times that of the semiconductor layer disposed below the light emitting layer.

When the refractive index of the low refractive index layer is decreased to about 2.0 to 1.6, the low refractive index layer can provide the same effects even if its thickness is smaller than the wavelength. This is because the amount of light seeping out from the light emitting layer into the low refractive index layer decreases because of the large difference in refractive index between the light emitting layer and the low refractive index layer.

Since the refractive index of about 2.0 to 1.6 corresponds to that of Al₂O₃ (sapphire) and AlN (aluminum nitride), substrates made of Al₂O₃ (sapphire) and AlN (aluminum nitride) can be used in the low refractive index layer to make the self-luminous device of the present invention.

By conducting a three-dimensional light wave simulation, the light extraction efficiency was determined for different flat surface structures of the self-luminous device that do not include two-dimensional periodic structures (FIG. 6). For each structure, the light extraction efficiency was determined using the light intensity for a single layer structure as the standard.

FIG. 6(a) is a plan view of a single layer structure. FIGS. 6(a) through 6(f) are side views of different single layer structures. FIG. 6(c) is an asymmetric structure with varying refractive index. FIG. 6(d) is a symmetric structure with the same refractive index. FIG. 6(e) is a multilayer structure including an intermediate layer disposed within the second semiconductor layer. FIG. 6(f) is a resin-coated structure in which the light emitting surface is coated with a resin cover 6. For each structure, the light extraction efficiency F is shown. The light extraction efficiency was determined by using the light intensity for the single layer structure as the standard. In FIG. 6, the refractive index of air to which the light emitting surface is exposed is assumed to be 1.0.

In the single layer structure shown in FIG. 6(b), the first semiconductor layer 2, the light emitting layer 3 and the second semiconductor layer 4 each have a refractive index of 2.8. The light intensity obtained by this structure is assigned a value of “1.00” and used as the standard.

In the asymmetric structure shown in FIG. 6(c), the first semiconductor layer 2, the light emitting layer 3 and the second semiconductor layer 4 have refractive indices of 2.5, 2.8 and 2.78, respectively. The light extraction efficiency obtained by this structure is determined to be “1.14” relative to the standard (i.e., the light intensity of the single layer structure).

In the symmetric structure shown in FIG. 6(d), the first semiconductor layer 2, the light emitting layer 3 and the second semiconductor layer 4 have refractive indices of 2.5, 2.8 and 2.5, respectively. The light extraction efficiency obtained by this structure is determined to be “1.02” relative to the standard (i.e., the light intensity of the single layer structure).

In the symmetric structure shown in FIG. 6(e), the first semiconductor layer 2, the light emitting layer 3, the second semiconductor layer 4 and the intermediate layer 5 disposed within the second semiconductor layer 4 have refractive indices of 2.5, 2.8, 2.5 and 2.5, respectively. The light extraction efficiency obtained by this structure is determined to be “1.02” relative to the standard (i.e., the light intensity of the single layer structure).

In the symmetric structure shown in FIG. 6(f), the light emitting surface of the single layer structure is coated with a resin with a refractive index of 1.45. The light extraction efficiency obtained by this structure is determined to be “2.74” relative to the standard (i.e., the light intensity of the single layer structure).

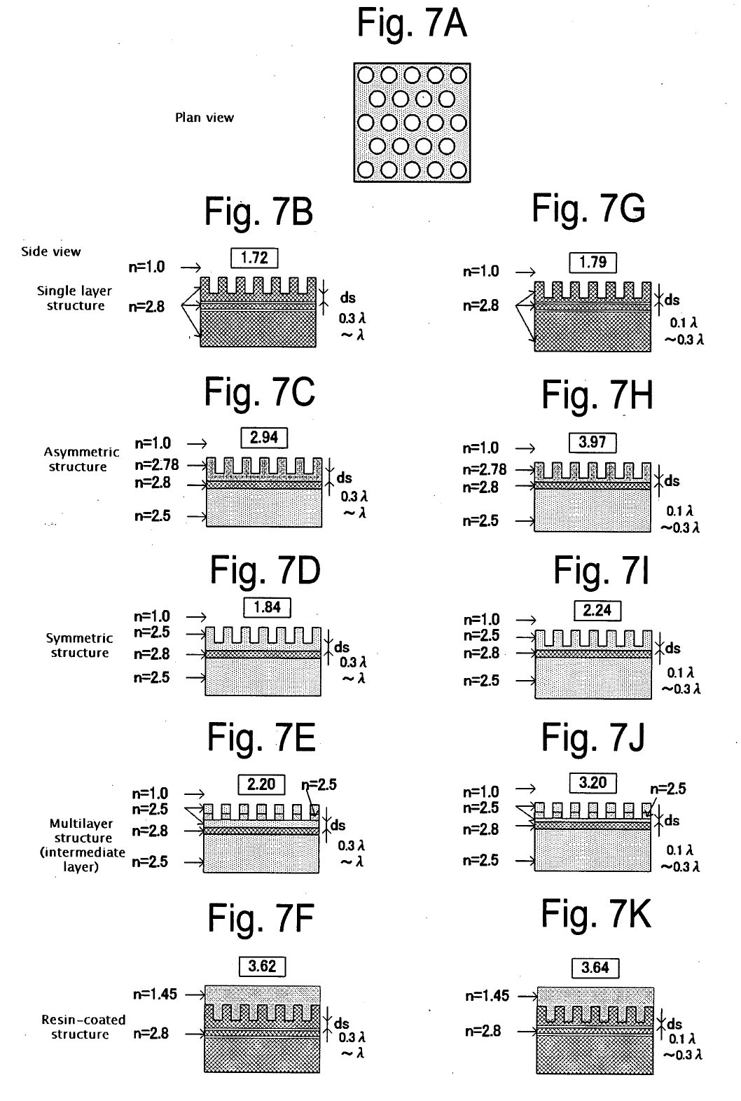

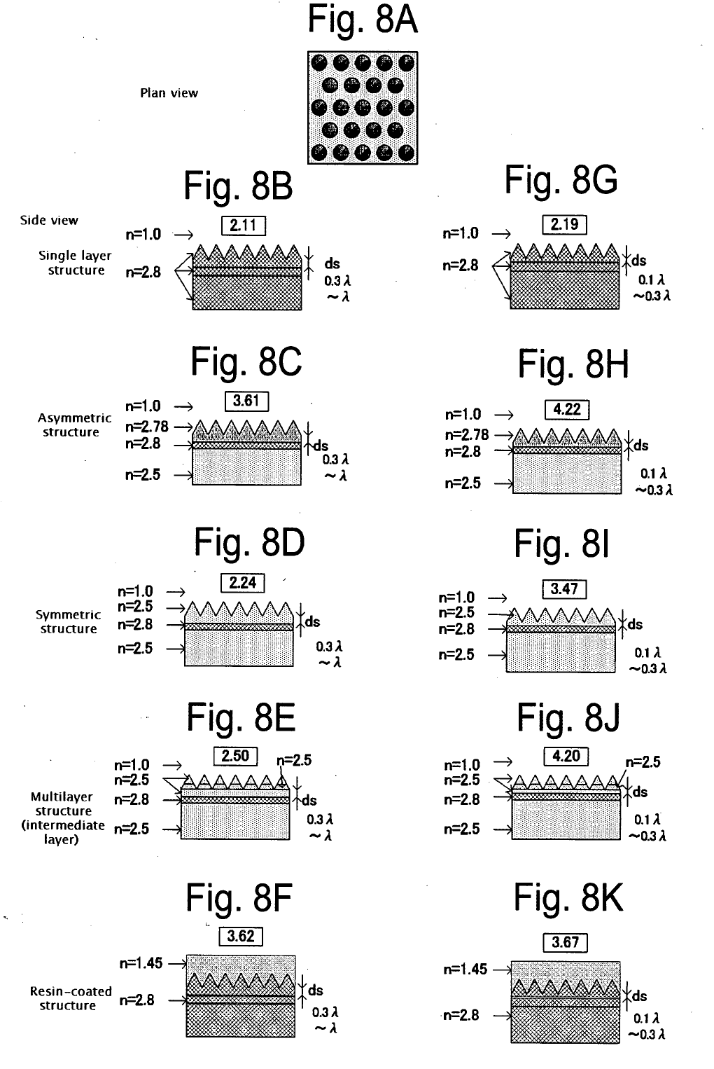

Referring next to FIGS. 7 and 8, the light extraction efficiency is shown for different structures of the self-luminous devices having respective two-dimensional periodic structures. The light extraction efficiency of each structure was determined using as the standard the light extraction efficiency of each of the corresponding flat surface structures of the self-luminous devices that do not include two-dimensional periodic structure (FIG. 6).

The optimum parameters determined by a three-dimensional light wave simulation are as follows: a=1.5λ, 2r=0.6a and dh=λ for each structure of the self-luminous device that has a dense array of circular pores as the two-dimensional periodic structure, and a=0.5λ and θ=63° for each structure of the self-luminous device that has a dense array of conical projections as the two-dimensional periodic structure.

FIG. 7 shows a comparison of the light extraction efficiency determined relative to the standard (i.e., the light extraction efficiency of the respective flat surface structures) for each of the following structures having a dense array of circular pores as the two-dimensional periodic structure: single layer structures (FIG. 7(b) and FIG. 7(g)), asymmetric structures with a varying refractive index (FIG. 7(c) and FIG. 7(h)), symmetric structures with the same refractive index (FIG. 7(d) and FIG. 7(i)), multilayer structures having an intermediate layer within the second semiconductor layer (FIG. 7(e) and FIG. 7(j)), and resin-coated structures in which the light emitting surface is coated with a resin cover (FIG. 7(f) and FIG. 7(k)).

FIG. 7(b) through FIG. 7(f) each show a thick construction in which the distance (ds) between the bottom of the two-dimensional periodic structure and the light emitting layer is in the range of 0.3λ to λ. FIG. 7(g) through FIG. 7(k) each show a thin construction in which the distance (ds) is in the range of 0.1λ to 0.3λ. In FIG. 7, the refractive index of air to which the light emitting surface is exposed is assumed to be 1.0.

The thick constructions in which the distance ds is in the range of 0.3λ to λ are first described with reference to FIG. 7(b) through FIG. 7(f).

In the single layer structure shown in FIG. 7(b), the first semiconductor layer 2, the light emitting layer 3 and the second semiconductor layer 4 each have a refractive index of 2.8. The light extraction efficiency of this structure as determined relative to the standard (i.e., the light intensity obtained for the structure of FIG. 6(b)=1.00) is “1.72.”

In the asymmetric structure shown in FIG. 7(c), the first semiconductor layer 2, the light emitting layer 3 and the second semiconductor layer 4 have refractive indices of 2.5, 2.8 and 2.78, respectively. The light extraction efficiency of this structure as determined relative to the standard (i.e., the light intensity obtained for the single layer structure of FIG. 6(b)) is “2.94.”

In the symmetric structure shown in FIG. 7(d), the first semiconductor layer 2, the light emitting layer 3 and the second semiconductor layer 4 have refractive indices of 2.5, 2.8 and 2.5, respectively. The light extraction efficiency of this structure as determined relative to the standard (i.e., the light intensity obtained for the single layer structure of FIG. 6(b)) is “1.84.”

In the multilayer structure shown in FIG. 7(e), the first semiconductor layer 2, the light emitting layer 3, the second semiconductor layer 4 and the intermediate layer 5 disposed within the second semiconductor layer 4 have refractive indices of 2.5, 2.8, 2.5, and 2.5, respectively. The light extraction efficiency of this structure as determined relative to the standard (i.e., the light intensity obtained for the single layer structure of FIG. 6(b)) is “2.20.”

In the symmetric structure shown in FIG. 7(f), the light emitting surface of the above-described single layer structure is coated with a resin having a refractive index of 1.45. The light extraction efficiency of this structure as determined relative to the standard (i.e., the light intensity obtained for the single layer structure of FIG. 6(b)) is “3.62.”

Next, the thin constructions in which the distance ds is in the range of 0.1λ to 0.3λ are described with reference to FIG. 7(g) through FIG. 7(k).

The single layer structure shown in FIG. 7(g) has the same construction as the structure shown in FIG. 7(b) except that ds is in the range of 0.1λ to 0.3λ. The light extraction efficiency of this structure relative to the standard (i.e., the light intensity obtained for the structure of FIG. 6(b)) is “1.79.”

The asymmetric structure shown in FIG. 7(h) has the same construction as the structure shown in FIG. 7(c) except that ds is in the range of 0.1λ to 0.3λ. The light extraction efficiency of this structure relative to the standard (i.e., the light intensity obtained for the structure of FIG. 6(b)) is “3.97.”

The symmetric structure shown in FIG. 7(i) has the same construction as the structure shown in FIG. 7(d) except that ds is in the range of 0.1λ to 0.3λ. The light extraction efficiency of this structure relative to the standard (i.e., the light intensity obtained for the structure of FIG. 6(b)) is “2.24.”

The multilayer structure shown in FIG. 7(j) has the same construction as the structure shown in FIG. 7(e) except that ds is in the range of 0.1λ to 0.3λ. The light extraction efficiency of this structure relative to the standard (i.e., the light intensity obtained for the structure of FIG. 6(b)) is “3.20.”

The symmetric structure shown in FIG. 7(k) has the same construction as the structure shown in FIG. 7(f) except that ds is in the range of 0.1λ to 0.3λ. The light extraction efficiency of this structure relative to the standard (i.e., the light intensity obtained for the structure of FIG. 6(b)) is “3.64.”

FIG. 8 shows a comparison of the light extraction efficiency determined relative to the standard (i.e., the light extraction efficiency of the respective flat surface structures) for each of the following structures having a dense array of conical projections as the two-dimensional periodic structure: single layer structures (FIG. 8(b) and FIG. 8(g)), asymmetric structures with varying refractive index (FIG. 8(c) and FIG. 8(h)), symmetric structures with the same refractive index (FIG. 8(d) and FIG. 8(i)), multilayer structures having an intermediate layer within the second semiconductor layer (FIG. 8(e) and FIG. 8(j)), and resin-coated structures in which the light emitting surface is coated with a resin cover (FIG. 8(f) and FIG. 8(k)).

FIG. 8(b) through FIG. 8(f) each show a thick construction in which the distance (ds) between the bottom of the two-dimensional periodic structure and the light emitting layer is in the range of 0.3λ to λ. FIG. 8(g) through FIG. 8(k) each show a thin construction in which the distance (ds) is in the range of 0.1λ to 0.3λ. In FIG. 8, the refractive index of air to which the light emitting surface is exposed is assumed to be 1.0.

The thick constructions in which the distance ds is in the range of 0.3λ to λ are first described with reference to FIG. 8(b) through FIG. 8(f).

In the single layer structure shown in FIG. 8(b), the first semiconductor layer 2, the light emitting layer 3 and the second semiconductor layer 4 each have a refractive index of 2.8. The light extraction efficiency of this structure as determined relative to the standard (i.e., the light intensity obtained for the structure of FIG. 6(b)) is “2.11.”

In the asymmetric structure shown in FIG. 8(c), the first semiconductor layer 2, the light emitting layer 3 and the second semiconductor layer 4 have refractive indices of 2.5, 2.8 and 2.78, respectively. The light extraction efficiency of this structure as determined relative to the standard (i.e., the light intensity obtained for the single layer structure of FIG. 6(b)) is “3.61.”

In the symmetric structure shown in FIG. 8(d), the first semiconductor layer 2, the light emitting layer 3 and the second semiconductor layer 4 have refractive indices of 2.5, 2.8 and 2.5, respectively. The light extraction efficiency of this structure as determined relative to the standard (i.e., the light intensity obtained for the single layer structure of FIG. 6(b)) is “2.24.”

In the multilayer structure shown in FIG. 8(e), the first semiconductor layer 2, the light emitting layer 3, the second semiconductor layer 4 and the intermediate layer 5 disposed within the second semiconductor layer 4 have refractive indices of 2.5, 2.8, 2.5 and 2.5, respectively. The light extraction efficiency of this structure as determined relative to the standard (i.e., the light intensity obtained for the single layer structure of FIG. 6(b)) is “2.50.”

In the symmetric structure shown in FIG. 8(f), the light emitting surface of the above-described single layer structure is coated with a resin having a refractive index of 1.45. The light extraction efficiency of this structure as determined relative to the standard (i.e., the light intensity obtained for the single layer structure of FIG. 6(b)) is “3.62.”

Next, the thin constructions in which the distance ds is in the range of 0.1λ to 0.3λ are described with reference to FIG. 8(g) through FIG. 8(k).

The single layer structure shown in FIG. 8(g) has the same construction as the structure shown in FIG. 8(b) except that ds is in the range of 0.1λ to 0.3λ. The light extraction efficiency of this structure relative to the standard (i.e., the light intensity obtained for the structure of FIG. 6(b)) is “2.19.”

The asymmetric structure shown in FIG. 8(h) has the same construction as the structure shown in FIG. 8(c) except that ds is in the range of 0.1λ to 0.3λ. The light extraction efficiency of this structure relative to the standard (i.e., the light intensity obtained for the structure of FIG. 6(b)) is “4.22.”

The symmetric structure shown in FIG. 8(i) has the same construction as the structure shown in FIG. 8(d) except that ds is in the range of 0.1λ to 0.3λ. The light extraction efficiency of this structure relative to the standard (i.e., the light intensity obtained for the structure of FIG. 6(b)) is “3.47.”

The multilayer structure shown in FIG. 8(j) has the same construction as the structure shown in FIG. 8(e) except that ds is in the range of 0.1λ to 0.3λ. The light extraction efficiency of this structure relative to the standard (i.e., the light intensity obtained for the structure of FIG. 6(b)) is “4.20.”

The symmetric structure shown in FIG. 8(k) has the same construction as the structure shown in FIG. 8(f) except that ds is in the range of 0.1λ to 0.3λ. The light extraction efficiency of this structure relative to the standard (i.e., the light intensity obtained for the structure of FIG. 6(b)) is “3.67.”

The results of the simulation analysis shown in FIGS. 6, 7 and 8 are summarized in Table 1 below.

TABLE 1

| | Surface feature | | | | |
|---|---|---|---|---|---|
| | | | | Dense array of | |
| | | Dense array of | | conical | |
| | | circular pores | | projections | |
| | Flat | ds | ds | ds | ds |
| Structures | surface | (large) | (small) | (large) | (small) |
| Single layer | 1.00 | 1.72 | 1.79 | 2.11 | 2.19 |
| Asymmetric | 1.14 | 2.94 | 3.97 | 3.61 | 4.22 |
| structure | (1.00) | (2.58) | (3.48) | (3.17) | (3.70) |
| Symmetric | 1.02 | 1.84 | 2.24 | 2.24 | 3.47 |
| structure | (1.00) | (1.80) | (2.15) | (2.20) | (3.40) |
| Multilayer | 1.02 | 2.20 | 3.20 | 2.50 | 4.20 |
| structure | (1.00) | (2.17) | (3.14) | (2.45) | (4.11) |
| (Intermediate | | | | | |
| layer) | | | | | |
| Resin-coated | 2.74 | 3.62 | 3.64 | 3.62 | 3.67 |
| structure | (1.00) | (1.32) | (1.33) | (1.32) | (1.34) |

In Table 1, the bracketed numbers represent the ratios of the light extraction efficiency of the different structures relative to the corresponding standards (i.e., Assuming that the light extraction efficiency obtained for the respective flat surface structures that do not have two-dimensional structures=1.00).

As shown by the results of the simulation analysis, the light extraction efficiency of the resin-covered structure is 2.74 times higher than that of the single layer structure. This indicates that the increase in the light extraction efficiency by the two-dimensional periodic structure is at most 1.3 times in the resin-covered structure. While the F-value can be increased up to F=1.5 by adjusting each layer, F>>2 can only be achieved by adjusting the resin layer alone.

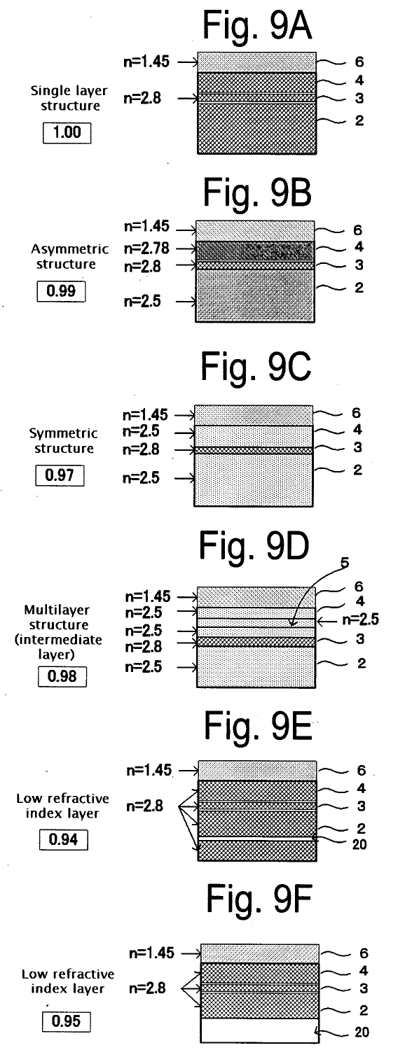

By conducting a three-dimensional light wave simulation, the light extraction efficiency was determined for different flat surface structures of the self-luminous device that are each coated with a resin cover and that do not include two-dimensional periodic structures (Shown in side views in FIG. 9). For each structure, the light extraction efficiency was determined using the light intensity for a single layer structure as the standard.

FIG. 9(a) is a side view of a single layer structure. FIG. 9(b) is an asymmetric structure with varying refractive index. FIG. 9(c) is a symmetric structure with the same refractive index. FIG. 9(d) is a multilayer structure including an intermediate layer disposed within the second semiconductor layer. FIG. 9(e) and FIG. 9(f) are each a structure that includes a refractive index layer below the light emitting layer with FIG. 9(e) having a low refractive index layer 20 disposed within the single layer and FIG. 9(f) having a low refractive index layer 20 disposed below the first layer 2. For each structure, the light extraction efficiency F is shown. The light extraction efficiency was determined by using the light intensity for the single layer structure as the standard (1.00). In FIG. 9, the refractive index of the resin cover 6 is 1.45.

In the single layer structure shown in FIG. 9(a), the first semiconductor layer 2, the light emitting layer 3 and the second semiconductor layer 4 each have a refractive index of 2.8 and the resin cover 6 has a refractive index of 1.45. The light intensity obtained by this structure is assigned a value of “1.00” and used as the standard.

In the asymmetric structure shown in FIG. 9(b), the first semiconductor layer 2, the light emitting layer 3 and the second semiconductor layer 4 have refractive indices of 2.5, 2.8 and 2.78, respectively. The light extraction efficiency obtained by this structure is determined to be “0.99” relative to the standard (i.e., the light intensity of the single layer structure of FIG. 9(a)).

In the symmetric structure shown in FIG. 9(c), the first semiconductor layer 2, the light emitting layer 3 and the second semiconductor layer 4 have refractive indices of 2.5, 2.8 and 2.5, respectively. The light extraction efficiency obtained by this structure is determined to be “0.99” relative to the standard (i.e., the light intensity of the single layer structure of FIG. 9(a)).

In the symmetric structure shown in FIG. 9(d), the first semiconductor layer 2, the light emitting layer 3, the second semiconductor layer 4 and the intermediate layer 5 disposed within the second semiconductor layer 4 have refractive indices of 2.5, 2.8, 2.5 and 2.5, respectively. The light extraction efficiency obtained by this structure is determined to be “0.98” relative to the standard (i.e., the light intensity of the single layer structure of FIG. 9(a)).

In the symmetric structure shown in FIG. 9(e), a low refractive index layer 20 having a refractive index of 2.8 or lower is interposed within the first semiconductor single layer 2 having a refractive index of 2.8. The light extraction efficiency obtained by this structure is determined to be “0.94” relative to the standard (i.e., the light intensity of the single layer structure of FIG. 9(a)).

In the symmetric structure shown in FIG. 9(f), a low refractive index layer 20 having a refractive index of 2.8 or lower is disposed below the first semiconductor layer 2 having a refractive index of 2.8. The light extraction efficiency obtained by this structure is determined to be “0.95” relative to the standard (i.e., the light intensity of the single layer structure of FIG. 9(a)).

It should be noted that since the light intensity of the single layer structure of FIG. 9(a) is “2.74” as shown in FIG. 6(f) relative to the light intensity obtained by the self-luminous device of FIG. 6(b) without the resin cover, the light intensity for each of the structures of FIG. 9(a) through FIG. 9(b) needs to be multiplied by a factor of 2.74.

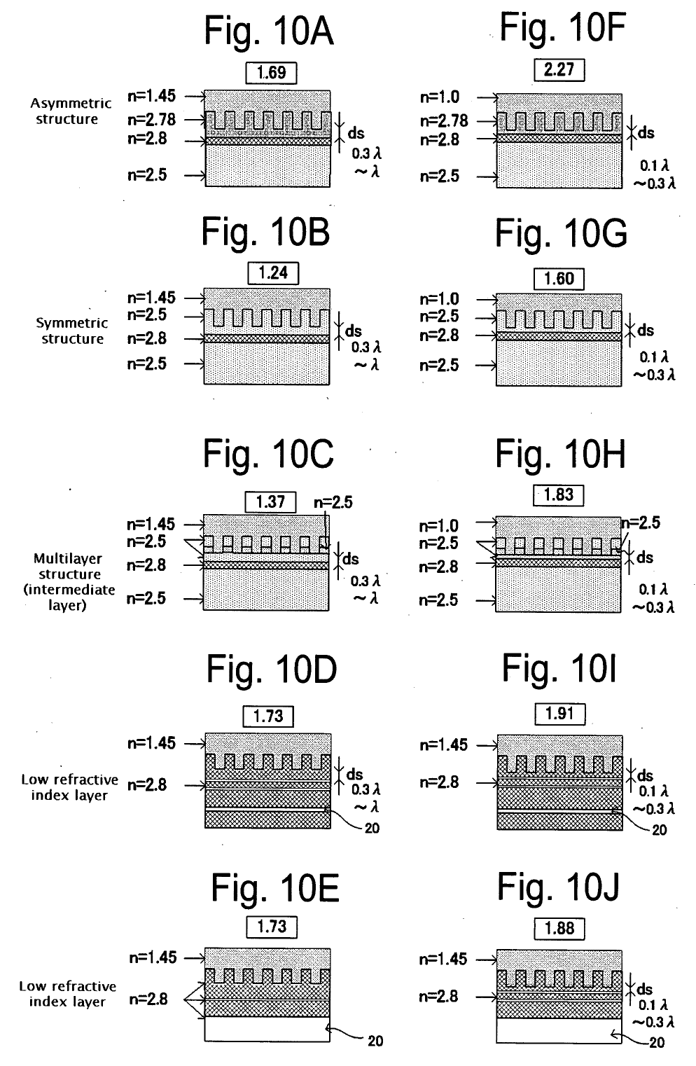

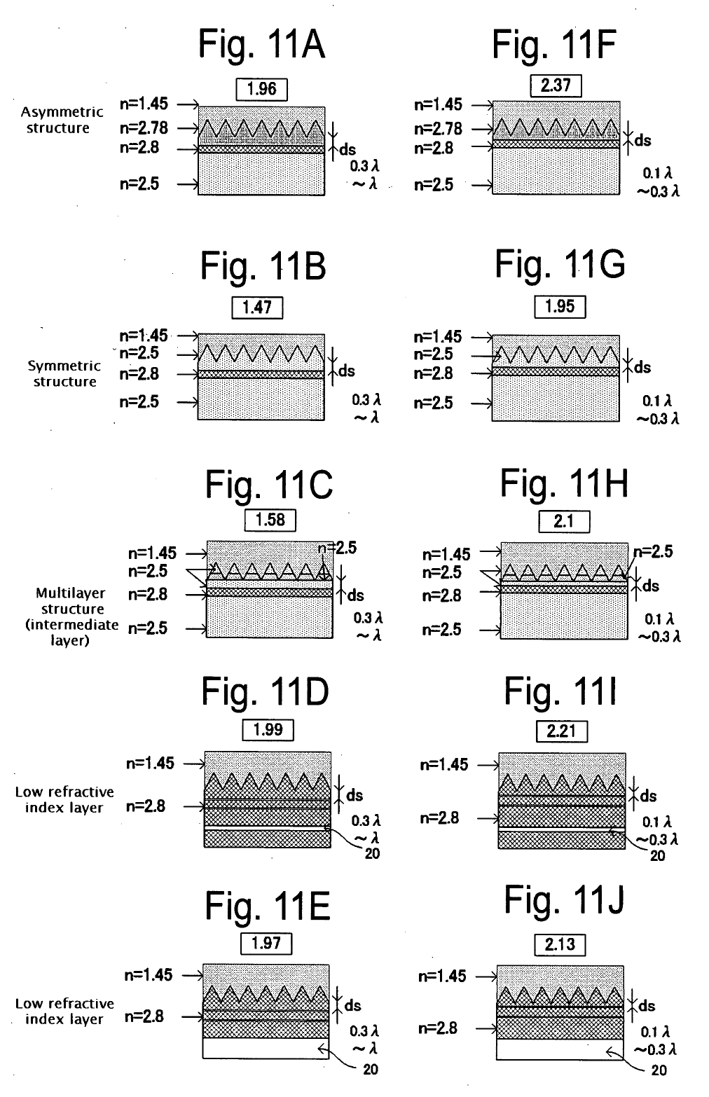

Referring next to FIGS. 10 and 11, the light extraction efficiency is shown for different coated structures of the self-luminous device having respective two-dimensional periodic structures. The light extraction efficiency of each structure was determined using as the standard the light extraction efficiency of each of the corresponding flat surface structures of the self-luminous devices that do not include two-dimensional periodic structures as shown in FIG. 9.

The optimum parameters determined by a three-dimensional light wave simulation are as follows: a=1.5λ, 2r=0.6a and dh=λ for each structure of the self-luminous device that has a dense array of circular pores as the two-dimensional periodic structure, and a=0.5λ and θ=63° for each structure of the self-luminous device that has a dense array of conical projections as the two-dimensional periodic structure.

FIG. 10 shows a comparison of the light extraction efficiency determined relative to the standard (i.e., the light extraction efficiency of the respective flat surface structures) for each of the following structures having a dense array of circular pores as the two-dimensional periodic structure: asymmetric structures with a varying refractive index (FIG. 10(a) and FIG. 10(f)), symmetric structures with the same refractive index (FIG. 10(b) and FIG. 10(g)), multilayer structures having an intermediate layer within the second semiconductor layer (FIG. 10(c) and FIG. 10(h)), structures having a low refractive index layer 20 interposed within the single layer (FIG. 10(d) and FIG. 10(i)), and structures having a refractive index layer below the light emitting layer (FIG. 10(e) and FIG. 10(j)).

FIG. 10(a) through FIG. 10(e) each show a thick construction in which the distance (ds) between the bottom of the two-dimensional periodic structure and the light emitting layer is in the range of 0.3λ to λ. FIG. 10(f) through FIG. 10(j) each show a thin construction in which the distance (ds) is in the range of 0.1λ to 0.3λ. The refractive index of the resin cover is 1.45.

The thick constructions in which the distance ds is in the range of 0.3λ to λ are first described with reference to FIG. 10(a) through FIG. 10(e).

In the asymmetric structure shown in FIG. 10(a), the first semiconductor layer 2, the light emitting layer 3 and the second semiconductor layer 4 have refractive indices of 2.5, 2.8 and 2.78, respectively. The light extraction efficiency of this structure as determined relative to the standard (i.e., the light intensity obtained for the single layer structure of FIG. 9(a)) is “1.69.”

In the symmetric structure shown in FIG. 10(b), the first semiconductor layer 2, the light emitting layer 3 and the second semiconductor layer 4 have refractive indices of 2.5, 2.8 and 2.5, respectively. The light extraction efficiency of this structure as determined relative to the standard (i.e., the light intensity obtained for the single layer structure of FIG. 9(a)) is “1.24.”

In the multilayer structure shown in FIG. 10(c), the first semiconductor layer 2, the light emitting layer 3, the second semiconductor layer 4 and the intermediate layer 5 disposed within the second semiconductor layer 4 have refractive indices of 2.5, 2.8, 2.5 and 2.5, respectively. The light extraction efficiency of this structure as determined relative to the standard (i.e., the light intensity obtained for the single layer structure of FIG. 9(a)) is “1.37.”

In the low refractive index structure shown in FIG. 10(d), a low refractive index layer 20 is disposed within the first semiconductor layer 2. The low refractive index layer 20 has a refractive index lower than that of the light emitting layer 3 (2.8) and equal to, or lower than, that of the other layers. The light extraction efficiency of this structure as determined relative to the standard (i.e., the light intensity obtained for the single layer structure of FIG. 9(a)) is “1.73.”

In the low refractive index structure shown in FIG. 10(e), a low refractive index layer 20 is disposed below the light emitting layer 3. The low refractive index layer 20 has a refractive index lower than that of the light emitting layer 3 (2.8) and equal to, or lower than, that of the other layers. The light extraction efficiency of this structure as determined relative to the standard (i.e., the light intensity obtained for the single layer structure of FIG. 9(a)) is “1.73.”

Next, the thin constructions in which the distance ds is in the range of 0.1λ to 0.3λare described with reference to FIG. 10(f) through FIG. 10(j).

The asymmetric structure shown in FIG. 10(f) has the same construction as the structure shown in FIG. 10(a) except that ds is in the range of 0.1λ to 0.3λ. The light extraction efficiency of this structure relative to the standard (i.e., the light intensity obtained for the structure of FIG. 9(a)) is “2.27.”

The symmetric structure shown in FIG. 10(g) has the same construction as the structure shown in FIG. 10(b) except that ds is in the range of 0.1λ to 0.3λ. The light extraction efficiency of this structure relative to the standard (i.e., the light intensity obtained for the structure of FIG. 9(a)) is “1.60.”

The multilayer structure shown in FIG. 10(h) has the same construction as the structure shown in FIG. 10(c) except that ds is in the range of 0.1λ to 0.3λ. The light extraction efficiency of this structure relative to the standard (i.e., the light intensity obtained for the structure of FIG. 9(a)) is “1.83.”

The structure shown in FIG. 10(i) with a low refractive index layer has the same construction as the structure shown in FIG. 10(d) except that ds is in the range of 0.1λ to 0.3λ. The light extraction efficiency of this structure relative to the standard (i.e., the light intensity obtained for the structure of FIG. 9(a)) is “1.91.”

The structure shown in FIG. 10(j) with a low refractive index layer has the same construction as the structure shown in FIG. 10(e) except that ds is in the range of 0.1λ to 0.3λ. The light extraction efficiency of this structure relative to the standard (i.e., the light intensity obtained for the structure of FIG. 9(a)) is “1.88.”

FIG. 11 shows a comparison of the light extraction efficiency determined relative to the standard (i.e., the light extraction efficiency of the respective flat surface structures) for each of the following structures having a dense array of conical projections as the two-dimensional periodic structure: asymmetric structures with varying refractive index (FIG. 11(a) and FIG. 11(f)), symmetric structures with the same refractive index (FIG. 11(b) and FIG. 11(g)), multilayer structures having an intermediate layer within the second semiconductor layer (FIG. 11(c) and FIG. 11(h)), structures having a low refractive index layer 20 interposed within the single layer (FIG. 11(d) and FIG. 11(i)), and structures having a low refractive index layer below the light emitting layer (FIG. 11(e) and FIG. 11(j)).

FIG. 11(a) through FIG. 11(e) each show a thick construction in which the distance (ds) between the bottom of the two-dimensional periodic structure and the light emitting layer is in the range of 0.3λ to λ. FIG. 11(f) through FIG. 11(j) each show a thin construction in which the distance (ds) is in the range of 0.1λ to 0.3λ. The refractive index of the resin cover is 1.45.

The thick constructions in which the distance ds is in the range of 0.3λ to λ are first described with reference to FIG. 11(a) through FIG. 11(e).

In the asymmetric structure shown in FIG. 11(a), the first semiconductor layer 2, the light emitting layer 3 and the second semiconductor layer 4 have refractive indices of 2.5, 2.8 and 2.78, respectively. The light extraction efficiency of this structure as determined relative to the standard (i.e., the light intensity obtained for the single layer structure of FIG. 9(a)) is “1.96.”

In the symmetric structure shown in FIG. 11(b), the first semiconductor layer 2, the light emitting layer 3 and the second semiconductor layer 4 have refractive indices of 2.5, 2.8 and 2.5, respectively. The light extraction efficiency of this structure as determined relative to the standard (i.e., the light intensity obtained for the single layer structure of FIG. 9(a)) is “1.47.”

In the multilayer structure shown in FIG. 11(c), the first semiconductor layer 2, the light emitting layer 3, the second semiconductor layer 4 and the intermediate layer 5 disposed within the second semiconductor layer 4 have refractive indices of 2.5, 2.8, 2.5 and 2.5, respectively. The light extraction efficiency of this structure as determined relative to the standard (i.e., the light intensity obtained for the single layer structure of FIG. 9(a)) is “1.58.”

In the low refractive index structure shown in FIG. 11(d), a low refractive index layer 20 is disposed within the first semiconductor layer 2. The low refractive index layer 20 has a refractive index lower than that of the light emitting layer 3 (2.8) and equal to, or lower than, that of the other layers. The light extraction efficiency of this structure as determined relative to the standard (i.e., the light intensity obtained for the single layer structure of FIG. 9(a)) is “1.99.”

In the low refractive index structure shown in FIG. 11(e), a low refractive index layer 20 is disposed below the light emitting layer 3. The low refractive index layer 20 has a refractive index lower than that of the light emitting layer 3 (2.8) and equal to, or lower than, that of the other layers. The light extraction efficiency of this structure as determined relative to the standard (i.e., the light intensity obtained for the single layer structure of FIG. 9(a)) is “1.97.”

Next, the thin constructions in which the distance ds is in the range of 0.1λ to 0.3λare described with reference to FIG. 11(f) through FIG. 11(j).

The asymmetric structure shown in FIG. 11(f) has the same construction as the structure shown in FIG. 11(a) except that ds is in the range of 0.1λ to 0.3λ. The light extraction efficiency of this structure relative to the standard (i.e., the light intensity obtained for the structure of FIG. 9(a)) is “2.37.”

The symmetric structure shown in FIG. 11(g) has the same construction as the structure shown in FIG. 11(b) except that ds is in the range of 0.1λ to 0.3λ. The light extraction efficiency of this structure relative to the standard (i.e., the light intensity obtained for the structure of FIG. 9(a)) is “1.95.”

The multilayer structure shown in FIG. 11(h) has the same construction as the structure shown in FIG. 11(c) except that ds is in the range of 0.1λ to 0.3λ. The light extraction efficiency of this structure relative to the standard (i.e., the light intensity obtained for the structure of FIG. 9(a)) is “2.1.”

The structure shown in FIG. 11(i) with a low refractive index layer has the same construction as the structure shown in FIG. 11(d) except that ds is in the range of 0.1λ to 0.3λ. The light extraction efficiency of this structure relative to the standard (i.e., the light intensity obtained for the structure of FIG. 9(a)) is “2.21.”

The structure shown in FIG. 11(j) with a low refractive index layer has the same construction as the structure shown in FIG. 11(e) except that ds is in the range of 0.1λ to 0.3λ. The light extraction efficiency of this structure relative to the standard (i.e., the light intensity obtained for the structure of FIG. 9(a)) is “2.13.”

The results of the simulation analysis shown in FIGS. 9, 10 and 11 are summarized in Table 2 below.

TABLE 2

| | Surface feature | | | | |
|---|---|---|---|---|---|
| | | | | Dense array of | |
| | | Dense array of | | conical | |
| | | circular pores | | projections | |
| | Flat | ds | ds | ds | ds |
| Structures | surface | (large) | (small) | (large) | (small) |
| Single layer | 1.00 | 1.32 | 1.33 | 1.32 | 1.34 |
| Asymmetric | 0.99 | 1.69 | 2.27 | 1.96 | 2.37 |
| structure | (1.00) | (1.71) | (2.29) | (1.98) | (2.39) |
| Symmetric | 0.97 | 1.24 | 1.60 | 1.47 | 1.95 |
| structure | (1.00) | (1.32) | (1.65) | (1.51) | (2.01) |
| Multilayer | 0.98 | 1.37 | 1.83 | 1.58 | 2.1 |
| structure | (1.00) | (1.40) | (1.87) | (1.61) | (2.14) |
| (Intermediate | | | | | |
| layer) | | | | | |
| Low refractive | 0.94 | 1.73 | 1.91 | 1.99 | 2.21 |
| index layer | (1.00) | (1.84) | (2.03) | (2.12) | (2.35) |
| (Within the | | | | | |
| single layer) | | | | | |
| Low refractive | 0.95 | 1.73 | 1.88 | 1.97 | 2.13 |
| index layer | (1.00) | (1.82) | (1.98) | (2.07) | (2.24) |
| (Bottom layer) | | | | | |

In Table 2, the bracketed numbers represent the ratios of the light extraction efficiency of the different structures relative to the corresponding standards (i.e., Assuming that the light extraction efficiency obtained for the respective flat surface structures that do not have two-dimensional structures=1.00).

As shown by the results of the simulation analysis, the light extraction efficiency is increased 1.73- to 2.13-folds by simply disposing a low refractive index layer below the light emitting layer.

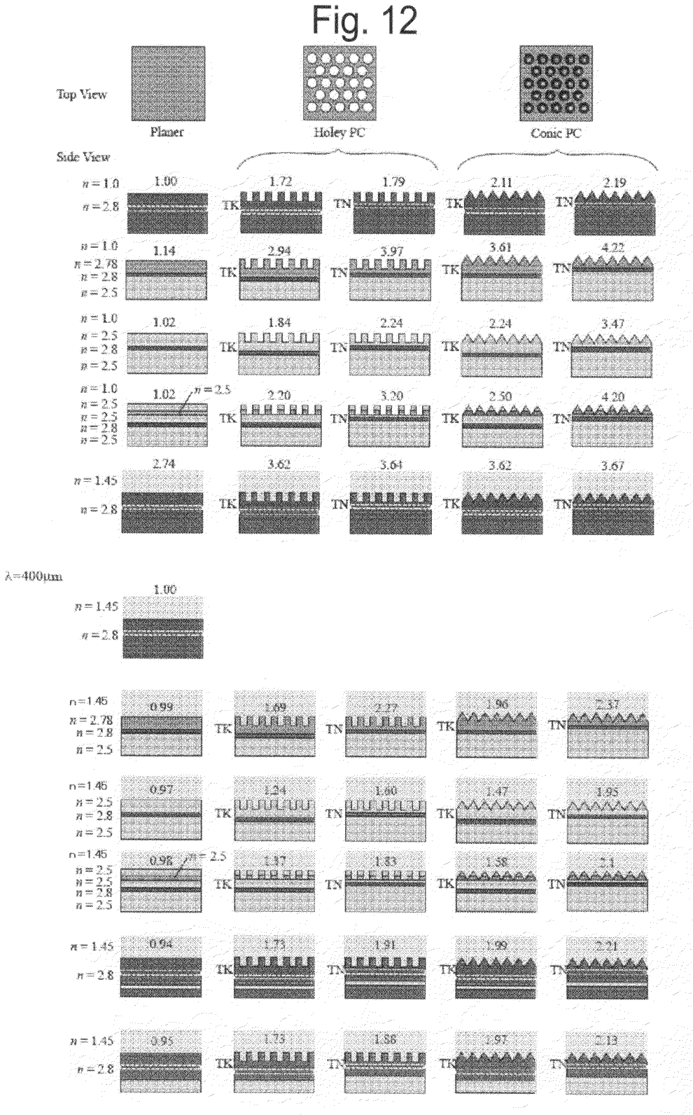

FIG. 12 collectively shows the results of FIG. 6 through FIG. 11. In FIG. 12, the leftmost column of the top half of the page corresponds to FIG. 6, the second and the third columns from the left of the top half correspond to FIG. 7, and the two right hand-side columns of the top half correspond to FIG. 8. The leftmost column of the bottom half of the page corresponds to FIG. 9, the second and the third columns from the left of the bottom half correspond to FIG. 10, and the two right hand-side columns of the bottom half correspond to FIG. 11.

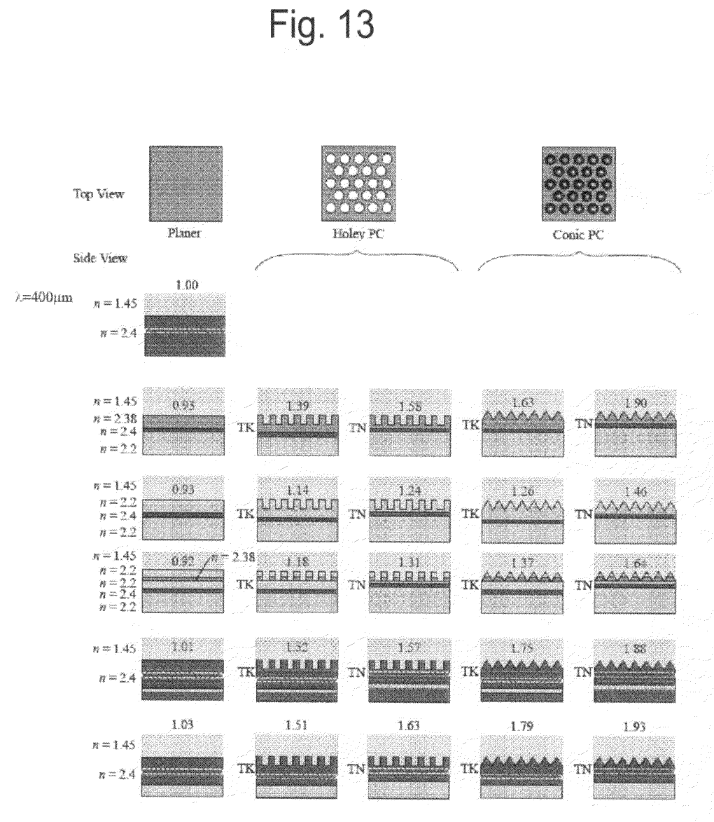

FIGS. 9, 10 and 11, and the bottom half of FIG. 12 show the results of simulations in which the wavelength λ=400 μm and the refractive index of the light emitting layer=2.8. In comparison, FIG. 13 shows the results of simulations in which the wavelength λ=400 μm and the refractive index of the light emitting layer=2.4. Although the light extraction efficiency was lower when the refractive index is 2.4 than when the refractive index is 2.8, the same tendency could be observed.

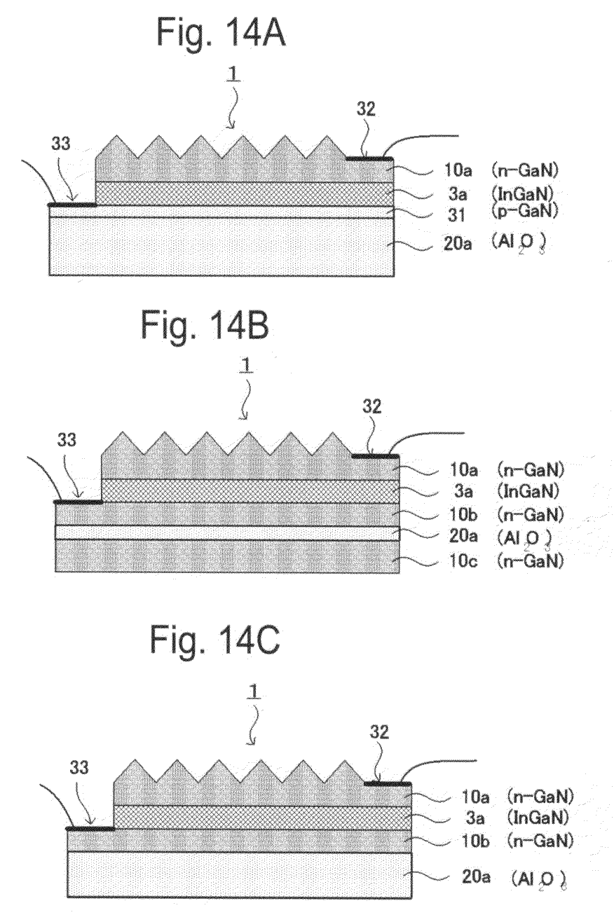

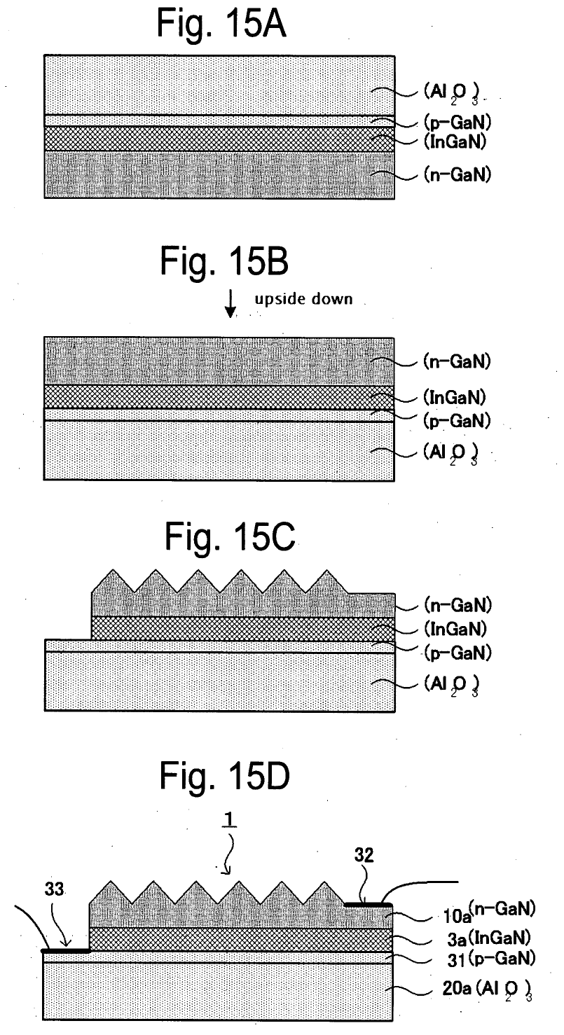

Exemplary constructions of a fourth embodiment of the self-luminous device of the present invention are now described with reference to FIGS. 14 and 15, as are the processes for making such constructions.

FIG. 14(a) shows a first exemplary construction of the fourth embodiment of the self-luminous device. This construction includes a light emitting layer 3a, a second layer 10a having a two-dimensional periodic structure and disposed above the light emitting layer 3a, a first layer (low refractive index layer) 20a disposed below the light emitting layer 3a, and a layer 31 interposed between the light emitting layer 3a and the low refractive index layer 20a. The light emitting layer 3a is formed of, for example, InGaN. The low refractive index layer 20a in the first layer is formed of, for example, AlGaN, Al₂O₃ (sapphire) or AlN (aluminum nitride). The second layer 10a and the layer 31 may be formed of n-GaN and p-GaN, respectively. Each can be formed by changing the Al composition in AlGaN.

An electrode 32 disposed in the second layer 10a and an electrode 33 disposed in the layer 33 supply an electric current to the light emitting layer 3a.

n-GaN can be used to make a thick layer: By using n-GaN in the second layer 10a, the thickness of the second layer 10a can be increased and the damage to the underlying light emitting layer 3a during the cutting of the two-dimensional periodic structure can be reduced. p-GaN has a lower electrical resistance than n-GaN and thus facilitates the supply of electric current to the surface of the light emitting layer 3a.

FIG. 14(b) shows a second exemplary construction of the fourth embodiment of the self-luminous device. This construction includes a light emitting layer 3a, a second layer 10a having a two-dimensional periodic structure and disposed above the light emitting layer 3a, first layers 10b and 10c disposed below the light emitting layer 3a, and a low refractive index layer 20a interposed between the first layers 10b and 10c.

The light emitting layer 3a is formed of, for example, InGaN. The low refractive index layer 20a in the first layer is formed of, for example, AlGaN, Al₂O₃ (sapphire) or AlN (aluminum nitride). The first layers 10b and 10c and the second layer 10a may be formed of n-GaN.

An electrode 32 disposed in the second layer 10a and an electrode 33 disposed in the first layer 10b supply an electric current to the light emitting layer 3a.

FIG. 14(c) is a third exemplary construction of the fourth embodiment of the self-luminous device. This construction includes a light emitting layer 3a, a second layer 10a having a two-dimensional periodic structure and disposed above the light emitting layer 3a, and a first layer 10b and a low refractive index layer 20a disposed below the light emitting layer 3a.

The light emitting layer 3a is formed of, for example, InGaN. The low refractive index layer 20a in the first layer is formed of, for example, AlGaN, Al₂O₃ (sapphire) or AlN (aluminum nitride). The first layer 10b and the second layer 10a may be formed of n-GaN.

An electrode 32 disposed in the second layer 10a and an electrode 33 disposed in the first layer 10b supply an electric current to the light emitting layer 3a.

FIG. 15 illustrates an exemplary process for making the fourth embodiment of the self-luminous device of the present invention. In this example, the construction of FIG. 14(a) is shown.

An InGaN layer to serve as the light emitting layer is first deposited on an n-GaN layer. A p-GaN layer and an Al₂O₃ (sapphire) layer are then deposited on the InGaN layer. The n-GaN layer and the p-GaN layer can be formed by changing the Al composition in AlGaN (FIG. 15(a)).

The stack of layers formed in FIG. 15(a) are then turned upside down so that the Al₂O₃ (sapphire) layer, the p-GaN layer, the InGaN layer and the n-GaN layer are stacked from the bottom up in this order (FIG. 15(b)).

The stack turned upside down in Fig. (a) is then cut from above to form a two-dimensional periodic structure and a flat surface for an electrode in the n-GaN layer and to expose part of the p-GaN layer (FIG. 15(c)).

An electrode 32 is then deposited on the flat surface formed in the n-GaN layer in FIG. 15(a). An electrode 33 is also deposited on the exposed surface of the p-GaN layer.

It is preferred not to apply a resin cover to self-luminous devices designed to emit light in the ultraviolet range since the resin cover tends to be decomposed by the ultraviolet rays. For this reason, two-dimensional periodic structures are preferably used in self-luminous devices coated with a resin cover to improve the light extraction efficiency.

Certain semiconductor-processing techniques can be used to form pores (orifices) or recesses in the semiconductor parts. Such techniques include laser processing by which light is irradiated to form deep features and masking to etch the semiconductor layer.

The results of simulations have demonstrated that the light extraction efficiency of a self-luminous device having a periodic structure of conical projections can decrease to half the maximum when the size of the self-luminous device is fixed and the grating constant λis varied up to 6λ. This suggests that the scattering in each element and the diffraction caused by the periodicity of photonic crystals contribute to the light extraction efficiency to the same extent.

Since the dependency of the grating constant a on the light extraction efficiency is small, the photonic crystals significantly contributes to the light extraction efficiency. Other surface structures may also be used to achieve comparable effects as long as the size of elements and the degree of the dense array of such structures are not significantly different from those of the optimum dense arrays that have a local and periodic structure.

Although the present invention has been described with regard to self-luminous devices that comprise semiconductor layers, the present invention is applicable not only to such semiconductor-based devices, but also to organic EL devices and other self-luminous devices that use glass substrates or layers of other compositions.

The present invention is applicable to semiconductor LEDs, organic EL devices, white lighting, illuminations, indicators, LED communications and other fields.

1. A self-luminous device comprising:
a first layer;
a light emitting layer overlaying the first layer; and
a second layer overlaying the light emitting layer, wherein a two-dimensional periodic structure is formed on a surface of the second layer or on a surface of a layer overlaying the second layer, and wherein a distance between a top of the light emitting layer and a bottom of the two-dimensional periodic structure is 0.1λ to 0.3λ, or 0.3λ to λ (where λ is the wavelength of light in vacuum).

2. The self-luminous device according to claim 1, wherein the refractive index of the first layer is different from that of the second layer so that the refractive indices of the two layers are asymmetric with respect to the light emitting layer interposed therebetween.

3. The self-luminous device according to claim 2, wherein the refractive index of the second layer is higher than that of the first layer.

4. The self-luminous device according to claim 1, wherein the two-dimensional periodic structure is a dense array of circular pores or a dense array of cone-shaped projections.

5. The self-luminous device according to claim 1, wherein the two-dimensional periodic structure is made of a photonic crystal.

6. The self-luminous device according to claim 1, wherein the two-dimensional periodic structure is made of a photonic quasicrystal that has a quasiperiodic structure that does not have translational symmetry, but does have long-range order and rotational symmetry in terms of refractive index.

7. The self-luminous device according to claim 1, wherein the first layer is made of n-GaN, the light emitting layer is made of InGaN and the second layer is made of p-GaN.

8. The self-luminous device according to claim 1, further comprising a resin layer overlaying the second layer.

9. A self-luminous device comprising:
a first layer;
a light emitting layer overlaying the first layer;
a second layer overlaying the light emitting layer; and
an intermediate layer formed within the second layer, wherein the intermediate layer has a refractive index close to that of the light emitting layer and is made of a medium that does not absorb light emitted from the light emitting layer.

10. The self-luminous device according to claim 9, wherein the intermediate layer has a thickness of 0.5λ or greater (where λ is the wavelength of light in vacuum).

11. The self-luminous device according to claim 9, wherein a two-dimensional periodic structure is formed on a surface of the second layer or on a surface of a layer overlaying the second layer,
wherein the intermediate layer is disposed within the two-dimensional periodic structure, and
wherein a distance between a top of the light emitting layer and a bottom of the two-dimensional periodic structure is 0.1λ to 0.3λ, or 0.3λ to λ (where λ is the wavelength of light in vacuum).

12. The self-luminous device according to claim 9, wherein the first layer, the second layer and the intermediate layer are each made of AlGaN with the Al composition of the intermediate layer being lower than those of the first layer and the second layer.

13. A self-luminous device comprising:
a first layer;
a light emitting layer overlaying the first layer;
a second layer overlaying the light emitting layer; and
an intermediate layer formed within the second layer, wherein a refractive index of the intermediate layer is higher than those of the first layer and the second layer.

14. The self-luminous device according to claim 13, wherein the intermediate layer has a thickness of 0.5λ or greater (where λ is the wavelength of light in vacuum).

15. The self-luminous device according to claim 13, wherein a two-dimensional periodic structure is formed on a surface of the second layer or on a surface of a layer overlaying the second layer,
wherein the intermediate layer is disposed within the two-dimensional periodic structure, and
wherein a distance between a top of the light emitting layer and a bottom of the two-dimensional periodic structure is 0.1λ to 0.3λ, or 0.3λ to λ (where λ is the wavelength of light in vacuum).

16. The self-luminous device according to claim 13, wherein the first layer, the second layer and the intermediate layer are each made of AlGaN with the Al composition of the intermediate layer being lower than those of the first layer and the second layer.

17. A self-luminous device comprising:
a first layer;
a light emitting layer overlaying the first layer; and
a second layer overlaying the light emitting layer, wherein a two-dimensional periodic structure is formed on a surface of the second layer or on a surface of a layer overlaying the second layer, and the first layer is a low refractive index layer that has a refractive index lower than that of the light emitting layer and equal to, or lower than, that of the second layer.

18. The self-luminous device according to claim 17, wherein the low refractive index layer has a thickness that is substantially the same as a wavelength of light emitted from the light emitting layer.

19. The self-luminous device according to claim 17, wherein the light emitting layer is made of InGaN, and the low refractive layer in the first layer is made of any of AlGaN, Al₂O₃ (sapphire) and AlN (aluminum nitride).

20. The self-luminous device according to claim 19, wherein the light emitting layer made of InGaN and an AlGaN layer having the two dimensional periodic structure are sequentially stacked on a sapphire substrate, and a layer having one of electrodes is disposed between the sapphire substrate and the light emitting layer, the other electrode being disposed on part of the AlGaN layer.

21. The self-luminous device according to claim 17, wherein a periodicity of two-dimensional periodic structure has a period in a range of ½ to 2 periods.
